(19) United States
(12) Patent Application Publication
(10) Pub. No.: US 2024/0124978 A1
(43) Pub. Date: Apr. 18, 2024

(54) GAS DIFFUSER PLATE COATED WITH EMISSIVITY-CONTROLLING THIN FILM AND METHODS OF FORMING SAME

(71) Applicant: Eugenus, Inc., San Jose, CA (US)

(72) Inventors: Behzad Mahmoudi, San Jose, CA (US); Mats Ingvar Larsson, Sunnyvale, CA (US); Selase Torkornoo, Sunnyvale, CA (US); Hae Young Kim, San Jose, CA (US); Cole Delany Green, San Francisco, CA (US); Bunsen Nie, Fremont, CA (US); James Long Wu, San Jose, CA (US); Chan Yong Park, Icheon-shi (KR); Deoghwan Kim, Yongin-si (KR); Siwon Ryu, Seoul (KR); Jae Jun Jung, Seoul (KR); Changhun Shin, Icheon-si (KR)

(21) Appl. No.: 18/482,791

(22) Filed: Oct. 6, 2023

Related U.S. Application Data
(60) Provisional application No. 63/379,432, filed on Oct. 13, 2022.

(51) Int. Cl. C23C 16/455

(52) U.S. Cl. CPC C23C 16/45559; C23C 16/45525

(57) ABSTRACT

A gas diffuser plate in a cyclic deposition chamber is disclosed. The gas diffuser plate as fabricated comprises a substrate diffuser plate having a substrate emissivity and a coating formed on the substrate diffuser plate. The gas diffuser plate having the substrate diffuser plate coated with the coating has an emissivity higher than the substrate emissivity. The coating comprises a first layer formed on the substrate diffuser plate and comprising a first material configured to modulate the emissivity of the gas diffuser plate, and a second layer comprising a second corrosion-resistant material. The first material comprises titanium nitride oxide (TiNₓO_{y}). The emissivity of the gas diffuser plate is at least partially based on the ratio of nitrogen and oxygen in TiNₓO_{y}.

### CROSS REFERENCE TO RELATED APPLICATIONS

This application claims the benefit of U.S. Provisional Patent Application Ser. No. 63/379,432, filed Oct. 13, 2022, entitled “GAS DIFFUSER PLATE COATED WITH EMISSIVITY-CONTROLLING THIN FILM,” which is incorporated herein by reference in its entirety.

### BACKGROUND

### Field

The disclosed technology relates generally to thin film deposition systems, and more particularly to showerhead assemblies for vapor deposition systems.

### Description of the Related Art

As semiconductor devices continue to scale in lateral dimensions, there is a corresponding scaling of vertical dimensions of the semiconductor devices, including thickness scaling of the functional thin films such as electrodes and dielectrics. Semiconductor fabrication involves various thin films that are deposited and patterned throughout the process flow. The thin films employed in semiconductor fabrication can be formed using various techniques, including wet and dry deposition methods. Wet deposition methods include, e.g., aerosol/spray deposition, sol-gel method and spin-coating. Dry deposition methods include physical vapor-based techniques, e.g., physical vapor deposition (PVD) and evaporation. Dry deposition methods additionally include precursor and/or chemical reaction-based techniques, e.g., chemical vapor deposition (CVD) and cyclic deposition such as atomic layer deposition (ALD).

### SUMMARY

In one aspect, a gas diffuser plate in a cyclic deposition chamber is disclosed. The gas diffuser plate as fabricated comprises a substrate diffuser plate having a substrate emissivity and a coating formed on the substrate diffuser plate, wherein the gas diffuser plate having the substrate diffuser plate coated with the coating has an emissivity higher than the substrate emissivity. In some aspects, the coating comprises a first layer formed on the substrate diffuser plate and comprising a first material configured to modulate the emissivity of the gas diffuser plate and a second layer comprising a second corrosion-resistant material. In some aspects, the first layer is configured to modulate the emissivity of the gas diffuser plate to a value between about 0.2 and about 0.9. In some aspects, a side of the gas diffuser plate coated with the coating is configured to face a wafer when present in the cyclic deposition chamber, wherein the first layer is configured to modulate the emissivity of the gas diffuser plate to match an emissivity of a deposited material on the wafer. In some aspects, the first material comprises titanium nitride oxide (TiNₓO_{y}) or a mixture of titanium oxide (TiOₓ) and titanium nitride (TiNₓ). In some aspects, the emissivity is at least partially based on the ratio of nitrogen and oxygen in TiNₓO_{y} or the mixture of TiOₓ and TiNₓ. In some aspects, the second layer is configured to reduce particle contamination generated from the corrosion of the substrate diffuser plate or the first layer in a cleaning process. In some aspects, the second layer is resistant to the corrosion of a cleaning gas when present in the cyclic deposition chamber. In some aspects, the cleaning gas comprises NF₃, F₂, Ar, ClF₃, or combinations thereof. In some aspects, the second material comprises yttrium aluminum garnet (YAG), Al₂O₃, Y₂O₃, or combinations thereof. In some aspects, the second material is transparent or translucent. In some aspects, the first layer of the first material is deposited by a method comprising plasma enhanced chemical vapor deposition (PECVD) process or magnetron sputtering. In some aspects, the second material is deposited by a method comprising atomic layer deposition (ALD). In some aspects, the first layer of the first material reduces the amount of radiation emission from the wafer being reflected by the gas diffuser plate. In some aspects, the second layer is placed on top of the first layer.

In another aspect, a gas diffuser plate for delivering precursor gases in a cyclic deposition chamber configured to deposit a material on a wafer is disclosed. The gas diffuser plate as fabricated comprises a substrate diffuser plate having a substrate emissivity; and a coating formed on the substrate diffuser plate at a side configured to face the wafer when present in the cyclic deposition chamber, wherein the gas diffuser plate having the substrate diffuser plate coated with the coating has an emissivity, and wherein difference between the value of the emissivity of the gas diffuser plate and the value of an emissivity of the material when deposited on the wafer is smaller than the difference between the value of the substrate emissivity and the value of the emissivity of the deposited material. In some aspects, the coating comprises a first layer formed on the substrate diffuser plate and comprising a first material configured to modulate the emissivity of the gas diffuser plate; and a second layer comprising a second material configured to reduce particle generation from the corrosion of the first layer or the substrate diffuser plate. In some aspects, the emissivity of the first layer is about 0.2 to about 0.9. In some aspects, the first material comprises titanium nitride oxide (TiNₓO_{y}) or a mixture of titanium oxide (TiOₓ) and titanium nitride (TiNₓ). In some aspects, the emissivity is at least partially based on the ratio of nitrogen and oxygen in TiNₓO_{y} or the mixture of TiOₓ and TiNₓ. In some aspects, the second layer is corrosion resistant to a cleaning gas. In some aspects, the cleaning gas comprises NF₃, F₂, Ar, ClF₃, or combinations thereof. In some aspects, the second material comprises yttrium aluminum garnet (YAG), Al₂O₃, Y₂O₃, or combinations thereof. In some aspects, the first layer of the first material is deposited by a method comprising plasma enhanced chemical vapor deposition (PECVD) process or magnetron sputtering. In some aspects, the first layer reduces the amount of radiation emission from a wafer being reflected by the gas diffuser plate. In some aspects, the second layer is placed on top of the first layer.

In another aspect, a method of fabricating a diffuser plate for delivering precursor gases in a cyclic deposition chamber is disclosed. The method comprises providing a substrate diffuser plate having a substrate emissivity; and coating the substrate diffuser plate with a coating such that the gas diffuser plate having the substrate diffuser plate coated with the coating as fabricated has an emissivity higher than the substrate emissivity. In some aspects, the coating comprises: forming a first layer of a first material having a selected emissivity such that the diffuser plate has the emissivity; and forming a second layer of a second material on top of the first material. In some aspects, the emissivity is between about 0.2 to about 0.7. In some aspects, forming the first layer of the first material comprising plasma enhanced chemical vapor deposition (PECVD) or magnetron sputtering. In some aspects, forming the second layer of the second material comprising ALD. In some aspects, the selected emissivity is at least partially related to an emissivity of the material to be deposited. In some aspects, the first material comprises titanium nitride oxide (TiNₓO_{y}). In some aspects, the selected emissivity of the first material is at least partially determined by the ratio of nitrogen and oxygen in TiNₓOy. In some aspects, the selected emissivity is at least partially related to an emissivity of the material to be deposited. In some aspects, the second material comprises yttrium aluminum garnet (YAG), Al₂O₃, Y₂O₃, or combinations thereof. In some aspects, the second material is resistant to a cleaning gas. In some aspects, the cleaning gas comprises NF₃, F₂, Ar, ClF₃, or combinations thereof. In some aspects, the second material is configured to reduce particle contamination.

In another aspect, an emissivity-controlling layer for a diffuser plate for a cyclic deposition process is disclosed. The emissivity-controlling layer configured to modulate an emissivity of a diffuser plate to an emissivity of a material to be deposited by the cyclic deposition process. In some aspects, the emissivity-controlling layer comprises titanium nitride oxide (TiNₓO_{y}). In some aspects, the emissivity of the emissivity-controlling layer is at least partially determined by the ratio of nitrogen and oxygen in TiNₓO_{y}.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and other features, aspects, and advantages of the present disclosure are described with reference to the drawings of certain embodiments, which are intended to illustrate certain embodiments and not to limit the invention.

FIG. 1 schematically illustrates a thin film deposition system including a deposition chamber configured to deliver precursors using a showerhead assembly comprising a diffuser plate, according to embodiments.

FIG. 2A illustrates a diffuser plate having a relatively low emissivity (brighter) and a diffuser plate having a relatively high emissivity (darker).

FIG. 2B illustrates reflectivity values of high emissivity regions (holes) and low emissivity regions (outer surface) of a fresh diffuser plate according to some embodiments.

FIG. 2C illustrates the reflectivity values of high emissivity regions (holes) and low emissivity regions (outer surface) of a stabilized diffuser plate according to some embodiments.

FIG. 3A illustrates different locations of a thermocouple wafer for temperature measurements.

FIG. 3B illustrates the normalized temperature values at different locations of a thermocouple wafer illustrated in FIG. 3A, measured in chambers with a diffuser plate having a relatively low emissivity (bright) and a diffuser plate having a relatively high emissivity (dark).

FIG. 3C is a box chart of the normalized temperature values illustrated in FIG. 3B.

FIGS. 4A-4C illustrate the front side, back side and the showerhead after a plurality deposition cycles.

FIG. 5 schematically illustrates emitted radiations during a deposition process.

FIGS. 6A-6C illustrate calculated emitted radiations for diffuser plate having different values of emissivity in ideal situations.

FIG. 7 schematically illustrates a double-layer coating for a diffuser plate according to some embodiments.

FIGS. 8A-8F illustrate the images of emissivity-controlling coatings with different compositions.

FIG. 9A illustrates an energy dispersive X-Ray spectrum (EDS) of an emissivity-controlling coating according to some embodiments.

FIG. 9B illustrates an X-ray diffraction (XRD) spectrum of three emissivity-controlling coatings according to some embodiments.

FIG. 10 illustrates calculated spectral emissivity versus wavelength curves of different emissivity-controlling coatings according to some embodiments or a diffuser plate under different conditions.

FIG. 11 illustrates a bar graph of emissivity values of different emissivity-controlling coatings according to some embodiments.

FIG. 12A illustrates a photograph of an uncoated sample substrate with coupon according to some embodiments.

FIG. 12B illustrates a colored height map with 50× magnification of the uncoated sample substrate in FIG. 12A.

FIG. 12C illustrates a three-dimensional (3D) map of the surface topography with 50× magnification of the uncoated sample substrate in FIG. 12A.

FIG. 12D illustrates the surface profile of a horizontal line 1 shown in FIG. 12B.

FIG. 12E illustrates the surface profile of a vertical line 2 shown in FIG. 12B.

FIG. 13A illustrates a photograph of a sample substrate with coupon coated with a TiNO layer according to some embodiments.

FIG. 13B illustrates a colored height map with 50× magnification of the sample substrate coated with a TiNO layer in FIG. 13A.

FIG. 13C illustrates a three-dimensional (3D) map of the surface topography with 50× magnification of the sample substrate coated with a TiNO layer in FIG. 13A.

FIG. 13D illustrates the surface profile of a horizontal line 1 shown in FIG. 13B.

FIG. 13E illustrates the surface profile of a vertical line 2 shown in FIG. 13B.

FIGS. 14A-14C illustrate photographs of different diffuser plates coated with a double-layer coating respectively.

FIG. 15A illustrates a photograph illustrating edge and center areas of a diffuser plate according to some embodiments.

FIGS. 15B-15D illustrate the emissivity values of different diffuser plates, comparing to the emissivity values of the corresponding TiNO films, and a stabilized diffuser plate.

### DETAILED DESCRIPTION OF THE PREFERRED EMBODIMENT

Cyclic deposition processes such as atomic layer deposition (ALD) processes can provide a relatively conformal thin films on relatively high aspect-ratio (e.g., 2:1) structures with high uniformity and thickness precision. While generally less conformal and uniform compared to ALD, thin films deposited using continuous deposition processes such as chemical vapor deposition (CVD) can provide higher productivity and lower cost. ALD and CVD can be used to deposit a variety of different films including elemental metals, metallic compounds (e.g., TiN, TaN, etc.), semiconductors (e.g., Si, III-V, etc.), dielectrics (e.g., SiO₂, AlN, HfO₂, ZrO₂, etc.), rare-earth oxides, conducting oxides (e.g., IrO₂, etc.), ferroelectrics (e.g., PbTiO₃, LaNiO₃, etc.), superconductors (e.g., Yba₂Cu₃O₇₋ₓ), and chalcogenides (e.g., GeSbTe), to name a few.

Some cyclic deposition processes such as atomic layer deposition (ALD) include alternatingly exposing a substrate to a plurality of precursors to form a thin film. The different precursors can alternatingly at least partly saturate the surface of the substrate and react with each other, thereby forming the thin film in a layer-by-layer fashion. There are different types of ALD, including time-based ALD and spatial ALD. In a time-based ALD, precursors are injected sequentially, reacting one at a time with active sites on the substrate surface. The exposures to precursors may be separated by a purge step in order to prevent mixing and reaction of precursors in the gas phase. The reaction is thus surface-limited and self-terminating, yielding uniform deposition. In addition, many ALD processes can allow for deposition of high-quality materials at substantially lower temperatures than with CVD, even near room temperature. ALD growth can take place in a particular temperature window, below which precursor molecules may not be sufficiently activated, or desorption can be too slow, and above which precursors can decompose at the surface or even before reaching it, and desorption can be too fast during the purge step.

Because of the layer-by-layer growth capability, ALD can enable precise control of the thickness and the composition, which in turn can enable precise control of various properties such as conductivity, conformality, uniformity, barrier properties and mechanical strength. In particular, due to thickness scaling that often accompanies feature size scaling in semiconductor devices, there is an increasing need to improve the within-wafer uniformity even for ALD that is already known to produce thin films with very high uniformity relative to other techniques. Although ALD films generally have excellent uniformity, there may be several reasons why the uniformity could be degraded during deposition. The uniformity could be degraded due to, e.g., overlapping reactant pulses, non-uniform precursor distribution, thermal self-decomposition of precursors, and non-uniformities in substrate temperature, to name a few.

Non-uniform precursor distributions can be caused by limited diffusion or mixing with carrier gases. For example, in ALD reactors, the precursors are introduced to the reaction chamber from individual source delivery lines, and the lines may be brought together to a common in-feed line prior to being introduced into the reaction chamber. Without being bound to any theory, a carrier gas, which may be flowing through all precursor delivery lines, can sometimes result in the carrier gas from one precursor delivery line serving as a diffusion barrier for the precursor flowing from a different precursor delivery line. Although the precursor would get properly mixed with the carrier gas in the individual source delivery line, the precursor may not properly spread out beyond the intersection of the common reactor in-feed line that is usually located a short distance from the substrate in the upstream direction.

To mitigate these concerns, some reactor chambers employ a means for distributing precursor/reactant and purge gases within the reactor volume. One such means includes a showerhead employed to effectively distribute and mix gases including precursors. Design variations of this hardware can range from flat designs to tapered designs. Gas distribution can be provided in one of several ways, including (1) across the surface of the showerhead via a plurality of holes supplied by one or more plenums, (2) fed from the center of the showerhead or (3) from one end to the other (also referred to as cross-flow).

In order to reduce the above-noted non-uniformity issues arising from insufficient mixing or diffusion, some ALD reactors, e.g., reactors with flat showerheads and distributed holes, a larger spacing between the showerhead and the substrate to increase the mixing and diffusion and reduce the effects of gas impingement on the substrate. However, increased spacing between the showerhead and the substrate comes at a price of longer ALD cycle times due to increased volume to fill with gases and purge. In time-based ALD, longer time needed to fill and purge the reactor can also worsen the non-uniformity arising from overlapping reactant pulses, because there may be longer leading and trailing edges for precursor pulses. In spatial ALD reactors with flat showerheads, spacing can be smaller but there may also typically a leading and trailing edge effect.

Furthermore, the inventors have found that, for the stringent requirements of today's semiconductor manufacturing specifications, process drift during ALD process may reduce film qualities, for example, by causing variation in film thickness, or causing variation in film qualities such as electrical or mechanical properties. The inventors have found that the ALD process stabilizes after seasoning or conditioning of a fresh diffuser plate, for example, by running a plurality of deposition cycles with test wafers (i.e., dummy wafers). The time to stabilize the ALD process is a process drift time, also known as conditioning time or seasoning time. The inventors have found that the radiosity in a deposition chamber, including the energy exchange between a showerhead and a wafer substrate caused by the temperature difference between the showerhead and the wafer substrate, can cause temperature fluctuation at the showerhead and on the wafer substrate. Such temperature fluctuation on the wafer substrate translates to within-wafer nonuniformities of various parameters, including growth rate, thickness, resistivity, step coverage, etc. The inventors have also found that, the temperature fluctuations on the wafer substrate caused by the radiation emission from the wafer and showerhead may be reduced after a fresh diffuser plate is used for a certain number of cycles. However, such stabilization requires relative long time and wastes many test wafers (dummy wafers), which reduces the productivity rate.

Thus, there is a need for a diffuser plate for a showerhead assembly for improved productivity (e.g., less time to stabilize the showerhead and substrate temperature) and uniformity of the thin films deposited in ALD systems. To address these and other sources of non-uniformities, various embodiments disclosed herein relate to a coating formed on a substrate diffuser plate, wherein the gas diffuser plate having the substrate diffuser plate coated with the coating has an emissivity higher than the substrate emissivity without the coating. In some embodiments, the coating comprises a double-layer coating for a diffuser plate for a showerhead assembly.

### A. SHOWERHEAD ASSEMBLY FOR ALD PROCESS

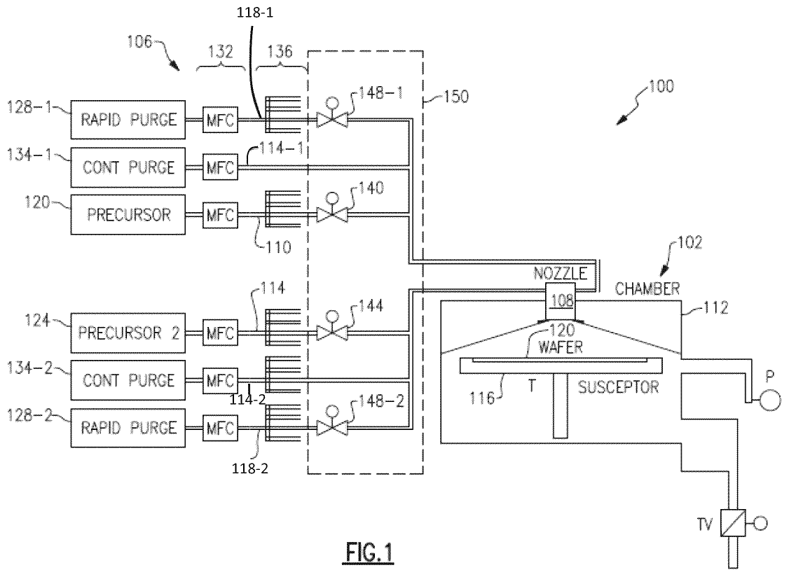

For illustrative purposes only, in the illustrated configuration of FIG. 1, the plurality of precursors may include a first precursor and a second precursor. The first precursor is stored in at least one first precursor source 120, and the second precursor is stored in at least one second precursor source 124. The precursor delivery system 106 is configured to deliver the first and second precursors from the first and second precursor sources 120, 124 into the deposition chamber 102 through first and second precursor delivery lines 110, 114, respectively. A rapid purge (RP) gas can be stored in at least two RP gas sources 128-1, 128-2. The precursor delivery system 106 is configured to deliver the rapid purge (RP) gas from the RP gas sources 128-1, 128-2 into the deposition chamber 102 through respective ones of RP gas delivery lines 118-1, 118-2.

The first and second precursors are configured to be delivered from the first and second precursor sources 120, 124, respectively, by independently actuating first and second precursor atomic layer deposition (ALD) valves 140 and 144 that are connected in parallel to the showerhead assembly 112. Additionally, the RP purge gas is configured to be delivered from the RP purge gas sources 128-1, 128-2 by independently actuating two respective purge gas atomic layer deposition (ALD) valves 148-1, 148-2 that are connected in parallel to the common gas distribution plate 112. The ALD valves 140, 144, 148-1 and 148-2 and the respective delivery lines connected to the showerhead assembly 112 can be arranged to feed the respective gases into the nozzle 108 through a multivalve block assembly 150, which may be attached to a lid of the deposition chamber 102. In the illustrated configuration, the ALD valves 140, 144, 148-1 and 148-2 are final valves before the respective gases are introduced into the deposition chamber 102.

In various configurations of the deposition chamber 102 described herein, a showerhead assembly 112 may include a diffuser plate facing the susceptor 116. As described herein, a diffuser plate refers to a plate comprising a plurality of holes for diffusing precursor gases prior to delivery into the chamber. In some configurations, the plurality of holes may be formed at a portion, e.g., a central portion, of the diffuser plate, while in other configurations, the plurality of holes may be formed substantially throughout the entire surface portion of the diffuser plate facing the substrate. In some configurations, the diffuser plate may be integrated as part of the showerhead assembly 112 while in other configurations, the diffuser plate may be configured as a separate component that can be attached between the showerhead assembly 112 the susceptor 116. In various configurations, the diffuser plate may directly face the substrate when present, or the substrate when no substrate is present, without intervening components.

By way of example only, the first and second precursors can include TiCl₄ and NH₃, respectively, that are delivered into the deposition chamber 102 from respective TiCl₄ and NH₃ sources through respective precursor delivery lines to form, e.g., TiN. The precursor delivery system can additionally be configured to deliver Ar as the purge gas into the process chamber from Ar sources through purge gas delivery lines. Purge gases may be delivered as a continuous purge (CP) gas, which may be delivered through precursor ALD valves, and/or as a rapid purge (RP) gas, which may be delivered through dedicated purge gas ALD valves as shown in FIG. 1. The illustrated precursor delivery system 100 can be configured to deliver Ar as an RP gas into the process chamber 102 from the purge gas sources 128-1, 128-2 through respective purge gas delivery lines and purge gas ALD valves 148-1, 148-2.

According to various embodiments, the thin film deposition system 100 is configured for thermal ALD without an aid of plasma. While plasma-enhanced processes such as plasma enhanced atomic layer deposition (PE-ALD) may be effective in forming conformal films on surfaces having relatively low aspect ratios, such processes may not be effective in depositing films inside vias and cavities having relative high aspect ratios. Without being limited by theory, one possible reason for this is that a plasma may not reach deeper portions of high aspect ratio vias under some circumstances. In these circumstances, different portions of the vias may be exposed to different amounts of the plasma, leading to undesirable structural effects arising from non-uniform deposition, such as thicker films being deposited near the opening of the via compared to deeper portions (sometimes called cusping or keyhole formation). For these reasons, a thermal cyclic vapor deposition such as thermal ALD may be more advantageous, because such thermal processes do not depend on the ability of the plasma to reach portions of the surface being deposited on.

### B. EMISSIVITY OF A DIFFUSER PLATE FOR A SHOWERHEAD ASSEMBLY

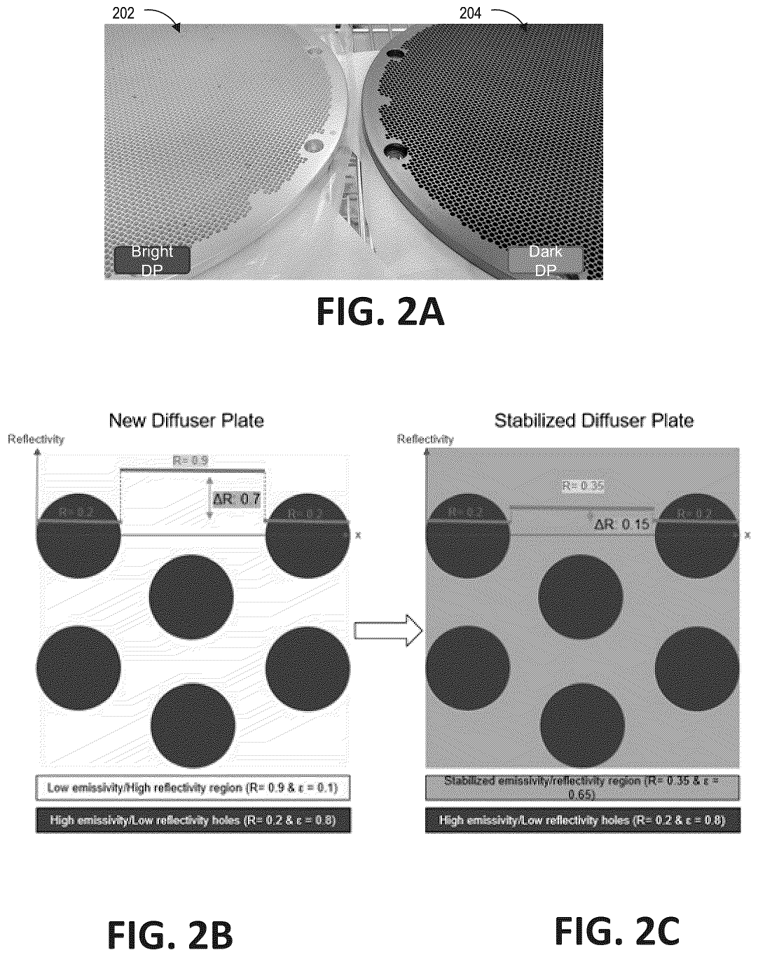

FIG. 2A illustrates a fresh diffuser plate and a dark diffuser plate. In some embodiments, the diffuser plate may comprise aluminum or aluminum-based material. As shown in FIG. 2A, the fresh diffuser plate has not been used in any deposition cycle and has a lighter silver color. The dark diffuser plate is a stabilized diffuser plate that has been used in a deposition process for a certain number of cycles. According to some embodiments, the temperature fluctuation is reduced for a stabilized diffuser plate comparing to a fresh diffuser plate.

The cyclic deposition process for some material is temperature sensitive. The increase in temperature causes growth rate to increase, such that the thickness of deposited thin film may be less uniform. When the temperature at the diffuser plate is too high, the atomic layer deposition may at least partially become a chemical vapor deposition as the precursors may react at or around the diffuser plate.

As described herein, emissivity is defined as the ratio of the energy radiated from a material's surface to that radiated from a perfect emitter, known as a blackbody, at the same temperature and wavelength and under the same viewing conditions. It is a dimensionless number between 0 (for a perfect reflector) and 1 (for a perfect emitter). The emissivity of a certain material may be related to temperature and wavelength of the radiation from the surface of the material.

The inventors have found that, in some embodiments, a fresh diffuser plate has a relatively low emissivity. The emissivity of the diffuser plate may increase with the ongoing deposition cycles in an ALD process, such as an ALD process for TiN deposition. After the diffuser plate goes through the stabilization process and reaches a relatively stable status, the emissivity becomes stable until a cleaning process, such as a dry cleaning or wet cleaning process, starts. The growth per cycle (GPC) with regard to the number of deposition cycles may be opposite to the emissivity with regard to the number of deposition cycles: the GPC decreases and reaches a stable rate when a diffuser plate goes from fresh to a stabilized status before a cleaning process. In some embodiments, after a certain number of cycles, the GPC decreases, indicating that the temperature of the substrate has decreased. The inventors have found that the reduction in temperature can be attributed to the formation of a thin film on the diffuser plate, which increases the emissivity. FIG. 2B illustrates the reflectivity values of high emissivity regions (holes) and low emissivity regions (outer surface) of a fresh diffuser plate according to some embodiments. As shown in FIG. 2B, the holes in a diffuser plate have a high emissivity value of about 0.8 and a low reflectivity value of 0.2. The outer surface of the fresh diffuser plate has a low emissivity value of about 0.1 and a high reflectivity value of about 0.9. Thus, there is a large emissivity difference between the holes and surface of a fresh diffuser plate.

FIG. 2C illustrates the reflectivity values of high emissivity region (holes) and low emissivity region (outer surface) of a stabilized diffuser plate according to some embodiments. As shown in FIG. 2C, the holes in a stabilized diffuser plate still have a high emissivity value of about 0.8 and a low reflectivity value of 0.2. However, the surface of the stabilized diffuser plate has a higher emissivity value of about 0.65 and a lower reflectivity value of about 0.35 comparing to the surface of a fresh diffuser plate. Thus, there is a smaller emissivity difference between the holes and surface of a stabilized diffuser plate comparing to that of a fresh diffuser plate.

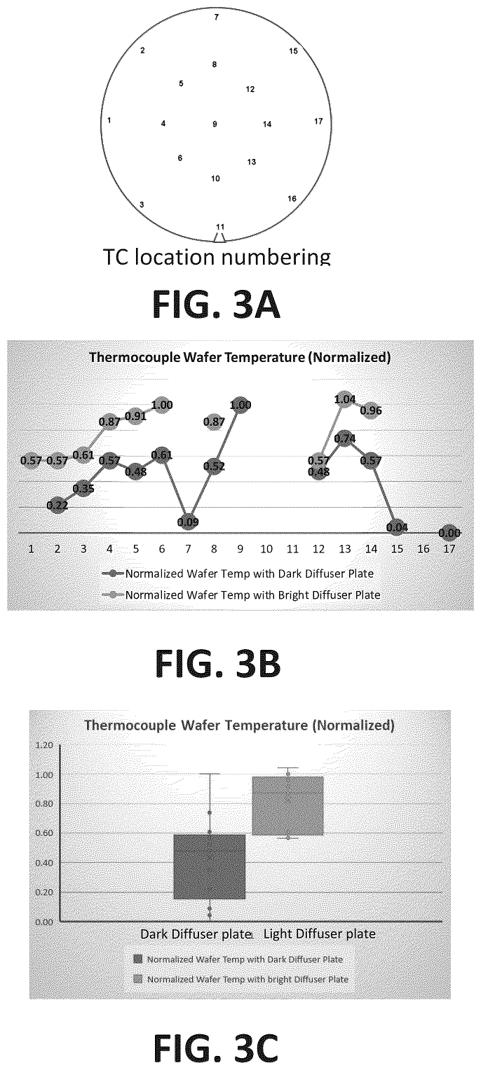

FIG. 3B shows the normalized temperature values measured at each of the positions 1-17 of a substrate wafer as illustrated in FIG. 3A in a chamber with a fresh diffuser plate (i.e., Bright DP) and the chamber with a dark diffuser plate (i.e., Dark DP), where the susceptor temperature is set to be nominally the same for the two conditions. FIG. 3C summarizes the normalized temperature values in FIG. 3B. The measured temperature values are normalized by (Tₘ−T_{Dark_min})/(T_{Dark_max}−T_{Dark_min}), wherein Tₘ is measured temperature at each position, T_{Dark_min} is the minimum temperature measured among all the positions 1-17 of the substrate wafer with a dark diffuser plate, and T_{Dark_min} is the maximum temperature measured among all the positions 1-17 of the substrate wafer with a dark diffuser plate. Table 1 summarizes the difference of the average temperature at the positions of an inner ring and an edge ring between a fresh diffuser plate and a dark diffuser plate.

TABLE 1

| | Δ (Dark DP − Bright DP) |
|---|---|
| Inner Ring (Average) | −7.5° C. |
| Edge Ring (Average) | −9.55° C. |

As shown in FIGS. 3B-3C and Table 1, the wafer temperatures with the fresh diffuser plate are higher than that with the dark diffuser plate at each location. Not to be bound by the theory, the temperature difference on a wafer substrate between using a fresh diffuser plate and a dark diffuser plate may be caused by the higher reflectivity or lower emissivity of a fresh diffuser plate relative to a dark diffuser plate, such that more radiation in an infrared (IR) wavelength range is reflected from the diffuser plate back to the wafer.

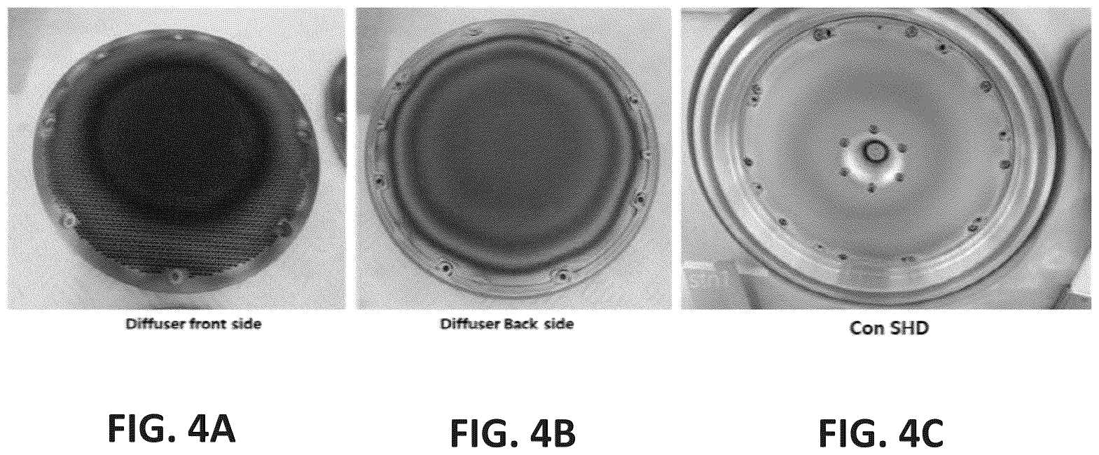

FIG. 4A and FIG. 4B show the front side and the back side of a diffuser plate after a plurality of deposition cycles respectively. FIG. 4C shows the condition of a surface of a solid part of the showerhead assembly in contact with the showerhead after a plurality of deposition cycles.

Based on the above observations, the inventors have discovered that it is advantageous to fabricate a diffuser plate having a coating formed thereon as fabricated, such that the emissivity starts out relatively high and stays relatively high with smaller drift in emissivity over time. The coating is such that the gas diffuser plate having a substrate diffuser plate coated with the coating has an emissivity higher than that of the substrate emissivity of the substrate diffuser plate without the coating.

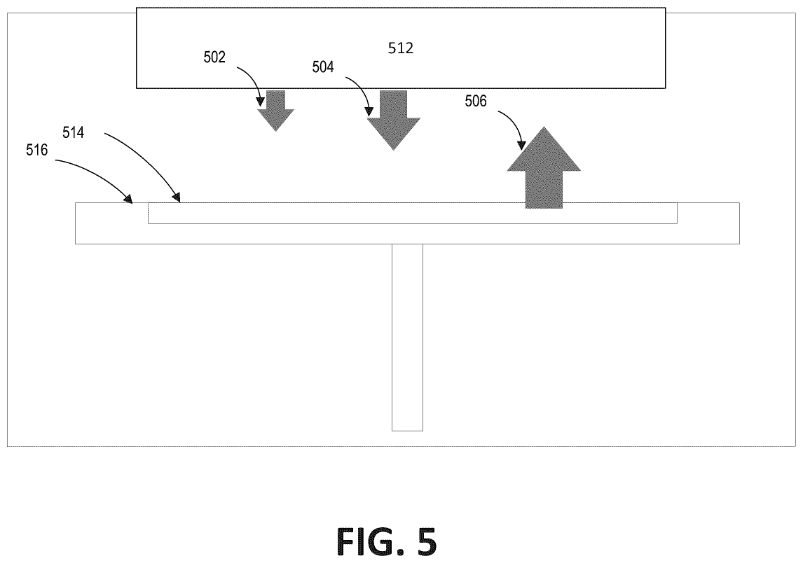

FIG. 5 schematically illustrates radiations emitted during a cyclic deposition process. As illustrated in FIG. 5, in a cyclic deposition system, the process temperature may be controlled by a heating element placed in the susceptor 516. The heating element may be set at a certain temperature Ta. The susceptor 516 may heat up a wafer 514 placed on top of the susceptor by radiation to a process temperature T_{bulk}. Normally, T_{bulk} may be lower than Tₐ. In some embodiments, the process temperature T_{bulk} may be about 400° C., 450° C., 500° C., 550° C., 600° C., 650° C., 700° C., 750° C., 800° C., 850° C., 900° C. or any temperature in a range defined by any of these temperatures. In some embodiments, a shower head 512 may be placed adjacent to the wafer. In some embodiments, the shower head 512 may comprise a diffuser plate facing the wafer. In some embodiments, the shower head 512 may be placed above the wafer. In some embodiments, the temperature of the diffuser plate may be about 200° C., 250° C., 300° C., 350° C., 400° C., 450° C., 500° C., or any temperature in a range defined by any of these temperatures. The temperature of the diffuser plate may be lower than the process temperature T_{bulk}. As there may be a temperature difference between the diffuser plate and the wafer 514, there is radiation from the wafer 514 to the shower head 512 (radiation 506). There may also be a radiation 502 from the shower head 512 to the wafer 514 due to the internal temperature of the diffuser plate. In some embodiments, a diffuser plate may comprise aluminum or aluminum-based material. In some embodiments, a fresh diffuser plate has a relatively low emissivity and a relatively high reflectivity. In some embodiments, a fresh diffuser plate is opaque. In some embodiments, a fresh diffuser plate has an absorbance of about 5% to about 20%. In some embodiments, a fresh diffuser plate has an absorbance of about 10%. In some embodiments, a fresh diffuser plate may have an emissivity of about from about 0.05 to about 0.1, about 0.05 to about 0.15, about 0.05 to about 0.2, for example, about 0.05, 0.06, 0.07, 0.08, 0.09, 0.10, 0.11, 0.12, 0.13, 0.14, 0.15, 0.16, 0.17, 0.18, 0.19, 0.20, or any number within a range defined by any of these values. In some embodiments, at least a portion of the radiation 506 from the wafer 514 to the shower head 512 may be reflected back to the wafer 514 (radiation 504). The diffuser plate and the wafer 514 may behave as radially coupled surfaces and emit infrared (IR) radiation to each other until an equilibrium is reached for the system. The temperature at the equilibrium state is designated herein as T_{bulk}. Not to be bound by the theory, the source of heat on a wafer substrate other than the heating element in the susceptor 516 may comprise the radiation reflected from the diffuser plate 512 back to the wafer substrate (radiation 504) due to the relatively low emissivity of a diffuser plate and the radiation 502 from the diffuser plate to the wafer 514. During the deposition, a dark deposition may gradually form on the surfaces of the diffuser plate as describe above. As the surface of the diffuser plate becomes darker, the emissivity of the diffuser plate may change, such that the radiosity of the system may change, which consequently causes instability and unwanted drift in the process temperature (T_{bulk}±ΔT) and the growth rate.

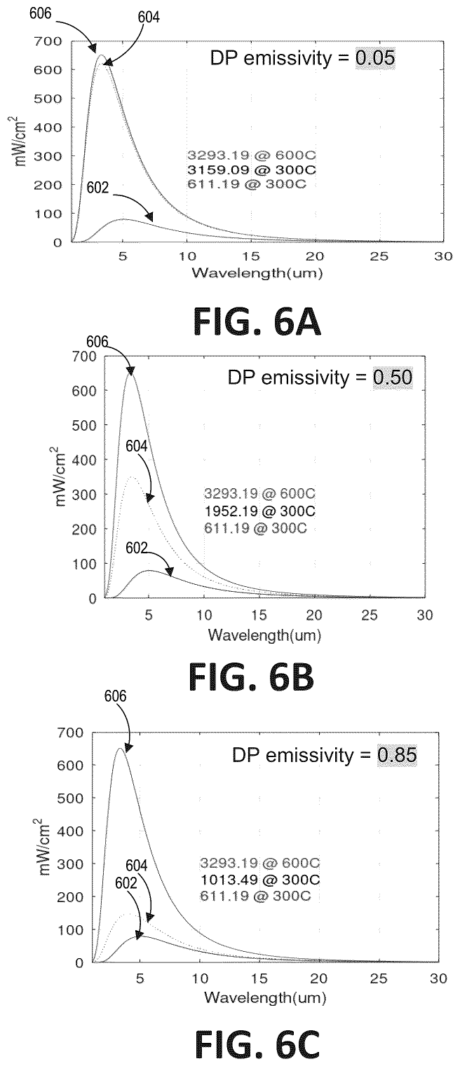

FIGS. 6A-6C illustrate calculated emitted radiations for a diffuser plate having different values of emissivity under ideal conditions where two infinite parallel surfaces are radiating to each other in vacuum. FIG. 6 illustrates the effect of emissivity variation of the diffuser plate on radiosity of the thermally coupled surfaces. For the calculations, the temperature of the wafer is set to be 600° C. and the diffuser plate is set to be 300° C. As shown in FIG. 6A-6C, the radiation of 600° C. surface is constant for different values of diffusion plate emissivity at 3293.2 mW/cm² (radiation 604), and the radiation of 300° C. surface is constant for different values of diffuser plate emissivity at 611.2 mW/cm² (radiation 602). In contrast, the radiation 606 reflected from the diffuser plate to the wafer decreases as the emissivity of the diffuser plate increases. With a higher emissivity value of about 0.85, the radiation 606 is reduced by 68% comparing to a lower emissivity value of about 0.05. Thus, the source of extra heat for a wafer which may cause process temperature fluctuations may be reduced by increasing the emissivity of the diffuser plate as fabricated, according to embodiments.

In addition, a diffuser plate comprises holes to distribute precursors. Holes generally have relatively higher emissivity comparing to the surface of a fresh diffuser plate. Thus, until a dark deposition is formed on the surface of the diffuser plate after a certain number of deposition cycles, the emissivity mismatch between the surface of a fresh diffuser plate and the holes of a diffuser plate may also cause variation of the process temperature.

### C. DOUBLE LAYER COATING FOR A DIFFUSER PLATE

As discussed above, the growth rate of a deposited thin film may be at least partially related to the deposition temperature, and one source of heat that causes variation of the process temperature is the reflection of radiation from the diffuser plate back to the wafer substrate. Such reflection of radiation from the diffuser plate to the wafer substrate may be caused by the low emissivity of a fresh diffuser plate, the emissivity mismatch between the wafer (or the deposited material) and the diffuser plate, and/or the emissivity mismatch between the fresh surface of a diffuser plate and the holes of a diffuser plate. Thus, there is a need to increase the emissivity of the diffuser plate or to match the emissivity value of the diffuser plate to that of the wafer or the material to be deposited.

Another concern for a vapor deposition process is particle contamination. During a vapor deposition process, the material to be deposited may be formed not only on a wafer, but also on the inner wall of the deposition chambers, the surfaces of a diffuser plate, or any other surfaces the precursors can reach. In addition, the byproducts may also be formed on those surfaces. In some embodiments, the diffuser plate may be cleaned in a cleaning process. In some embodiments, the cleaning process may be a wet cleaning process or a dry cleaning process. In some embodiments, a cleaning gas may be supplied into the deposition chamber to remove the deposited materials or byproducts from the surfaces other than the wafer. In some embodiments, the cleaning gas may be corrosive. In some embodiments, the cleaning gas may comprise NF₃, F₂, Ar, ClF₃, or combinations thereof. Under some circumstances, the cleaning gas may be corrosive or erosive to the diffuser plate. In some other circumstances, the precursors used for deposition, such as TiCl₄, NH₃, SiH₂Cl₂ (DCS), SiH₄ (Silane), HCl, NHCl₄, Adducts, may be corrosive to the diffuser plate. Accordingly, the diffuser plate may be corroded or eroded by certain chemicals supplied to or generated during the deposition process. In those circumstances, the corrosion of the diffuser plate may generate particles and fall from the diffuser plate during deposition process, such that the deposited thin film may be contaminated. Thus, there is a need for a corrosion-resistant coating layer for a diffuser plate to reduce the particles generated during the cleaning or corrosion of the diffuser plate by cleaning gas, precursors, or any chemicals generated during processing.

To address the problem of temperature fluctuation due to radiosity of the deposition system and particle contamination, a diffuser plate according to various embodiments comprises a double layer coating configured to control emissivity and reduce particle contamination is disclosed.

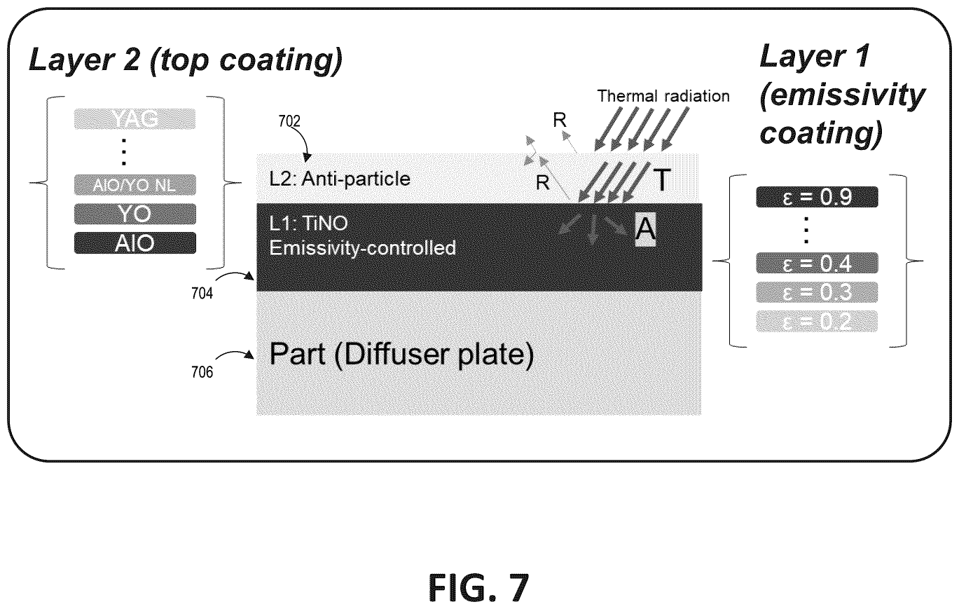

FIG. 7 schematically illustrates a double-layer coating for a diffuser plate according to some embodiments. As shown in FIG. 7, a double-layer coating is deposited on top of the diffuser plate 706. In some embodiments, the double layer coating may comprise an emissivity-controlling layer 704 and an anti-contamination layer 702.

### Emissivity-Controlling Layer

In some embodiments, the emissivity-controlling layer may have different emissivity values. In some embodiments, the emissivity of the emissivity-controlling layer may be selected according to needs. In some embodiments, the emissivity is selected at least partly related to the emissivity of the material to be deposited on the wafer. In some embodiments, the emissivity of the emissivity controlling layer may be about 0.15 to about 0.9, about 0.2 to about 0.8, about 0.2 to about 0.7, is about 0.9, 0.85, 0.8, 0.75, 0.7, 0.65, 0.6, 0.55, 0.5, 0.45, 0.4, 0.35, 0.3, 0.25, 0.2, 0.15, or any number in a range defined by any of these values.

In some embodiments, the emissivity-controlling layer may comprise TiNₓO_{y}. In some embodiments, the emissivity of the emissivity-controlling layer may at least be partially related to the ratio of the amount of N to O (i.e., x to y ratio) in TiNₓOy. In some embodiment, the ratio of x to y in TiNₓO_{y} may be from about 0 to about 30, from about 0 to about 25, from about 0 to about 20, from about 0 to about 15, from about 0 to about 10, is about 0.2, 0.3, 0.4, 0.5, 0.6, 0.7, 0.8, 0.9, 1, 1.1, 1.2, 1.3, 1.4, 1.5, 1.6, 1.7, 1.8, 1.9, 2, 2.5, 3, 3.5, 4, 4.5, 5, 5.5, 6, 6.5, 7, 7.5, 7.6, 7.7, 7.8, 7.9, 8, 9, 10, 11, 12, 13, 14, 15, 16, 17, 18, 19, 20, 21, 22, 23, 24, 25, 26, 27, 28, 29, 30, or any number in a range defined by any of these values. In some embodiments, an emissivity-controlling layer with a higher ratio of x to y has a lower emissivity comparing to an emissivity-controlling layer with a lower ratio of x to y. In some embodiments, an emissivity-controlling layer comprising a larger amount of nitrogen has a smaller emissivity value comparing to an emissivity-controlling layer comprising a smaller amount of nitrogen.

The inventors have found that, in particular implementations, by controlling the x:y ratio between about 7.7 to 0.5, the emissivity of the emissivity-controlling layer can be tuned to be between about 0.22 and 0.72. Without limitation, some specifically tuned examples of tuned emissivity-controlling layer are shown in Table 2. For example, in one specific implementation, an emissivity-controlling layer comprising a larger amount of oxygen has a larger emissivity value comparing to an emissivity-controlling layer comprising a smaller amount of nitrogen. In another specific implementation, an emissivity-controlling layer with a x to y ratio of about 0.5 has an emissivity value of about 0.7. In another specific implementation, an emissivity-controlling layer with a x to y ratio of about 0.7 has an emissivity value of about 0.65. In another specific implementation, an emissivity-controlling layer with a x to y ratio of about 1.1 has an emissivity value of about 0.55. In another specific implementation, an emissivity-controlling layer with a x to y ratio of about 1.9 has an emissivity value of about 0.4. In another specific implementation, an emissivity-controlling layer with a x to y ratio of about 2.0 has an emissivity value of about 0.3. In yet another specific implementation, an emissivity-controlling layer with a x to y ratio of about 7.7 has an emissivity value of about 0.2. It will be appreciated that the emissivity can be tailored to be in a range defined by any of these values by correspondingly adjusting the x:y ratio.

In some embodiments, the emissivity controlling layer comprises Ti in an amount of, of about, of at least, of at least about of at most, or of at most about 20 at %, 22 at %, 25 at %, 27 at %, 30 at %, 31 at %, 32 at %, 33 at %, 34 at %, 35 at %, 36 at %, 37 at %, 38 at %, 39 at %, 40 at %, 41 at %, 42 at %, 43 at %, 44 at %, 45 at %, or any range of values therebetween. In some embodiments, the emissivity controlling layer comprises N in an amount of, of about, of at least, of at least about of at most, or of at most about 15 at %, 20 at %, 21 at %, 22 at %, 23 at %, 24 at %, 25 at %, 26 at %, 27 at %, 28 at %, 29 at %, 30 at %, 31 at %, 32 at %, 33 at %, 34 at %, 35 at %, 36 at %, 37 at %, 38 at %, 39 at %, 40 at %, 41 at %, 42 at %, 43 at %, 44 at %, 45 at %, 46 at %, 47 at %, 50 at %, 51 at %, 52 at %, 53 at %, 54 at %, 55 at %, 56 at %, 57 at %, 58 at %, 59 at %, 60 at %, 65 at %, 70 at %, or any range of values therebetween. In some embodiments, the emissivity controlling layer comprises O in an amount of, of about, of at least, of at least about of at most, or of at most about 5 at %, 6 at %, 7 at %, 7.5 at %, 8 at %, 9 at %, 10 at %, 15 at %, 16 at %, 17 at %, 18 at %, 19 at %, 20 at %, 21 at %, 22 at %, 23 at %, 24 at %, 25 at %, 26 at %, 27 at %, 28 at %, 29 at %, 30 at %, 31 at %, 31.5 at %, 32 at %, 33 at %, 34 at %, 35 at %, 36 at %, 37 at %, 38 at %, 39 at %, 40 at %, 41 at %, 42 at %, 43 at %, 44 at %, 45 at %, 50 at %, 55 at %, 60 at %, or any range of values therebetween.

In some embodiments, the emissivity-controlling layer comprises TiNₓ and TiOₓ. In some embodiments, the emissivity-controlling layer comprises poly-crystalline. In some embodiments, the emissivity of the emissivity-controlling layer may at least be partially related to the ratio of titanium, nitrogen, and oxygen in the emissivity-controlling layer.

In some embodiments, emissivity-controlling layer has a relatively high emissivity such that the emissivity-controlling layer may have high absorbance and low reflectivity of radiation from the wafer. In those embodiments, the emissivity-controlling layer may absorb a large amount of the thermal radiation from the wafer and reduce the radiant heat exchange between the wafer and diffuser layer. In those embodiments, the temperature of the wafer may be more stabilized as there would be less heat reflected by the diffuser plate.

The amount of radiation reflected, absorbed, and transmitted should be 100%. If a coating is fully opaque, the transmitted radiation is 0, and the reflected and absorbed radiation should be 100%. If a coating is fully transparent, the transmitted radiation is 100%, and the experimental reflectance measurement equals to reflectance of the substrate beneath the transparent coating. If a coating is translucent, the transmitted radiation is between 0 to 100%, and the experimental reflectance reading is partially from coating and partially from the substrate beneath the coating. In some embodiments, the stabilized diffuser plate has an emissivity of about 0.60 to about 0.75 within the IR spectrum as shown, for example, about 0.6, 0.65, 0.70, 0.75, or any value in a range defined by any of these values. In some embodiments, the stabilized diffuser plate is opaque with about 20%-40% absorbance. In some embodiments, a coating with a high emissivity is a coating with an emissivity comparable to, similar to, or larger than the emissivity of a stabilized diffuser plate.

In some embodiments, the stabilized diffuser plate has an emissivity of about 0.65. In some embodiments, a coating with a high emissivity is a coating having an emissivity higher than a stabilized diffuser plate. In some embodiments, the emissivity-controlling coating should provide certain emissivity value that is much higher than the bare aluminum emissivity value. In some embodiments, the emissivity-controlling coating should provide certain emissivity value that is at least as high as the stabilized diffuser plate. In some embodiments, a specific emissivity value may be selected for an emissivity-controlling layer. In some embodiments, the emissivity is selected to match the emissivity of a wafer or a material to be deposited on the wafer.

Advantageously, an ALD process using a diffuser plate coated with an emissivity-controlling layer according to some embodiments has less process drift comparing to an ALD process using a diffuser plate without such emissivity-controlling layer. Thus, the drift time for an ALD process may be much less using a diffuser plate coated with the emissivity-controlling layer according to some embodiments, such that the productivity rate is increased.

### Thickness and Roughness of Emissivity-Controlling Layer

In some embodiments, the emissivity-controlling layer may be about 100 nm to about 10 μm, may be about 100 nm, 200 nm, 500 nm, 700 nm, 900 nm, 1 μm, 2 μm, 3 μm, 5 μm, 7 μm, 9 μm, 10 μm, or any number in a range defined by any of these values.

In some embodiments, the emissivity-controlling layer is conformal, for example, the thickness of the emissivity-controlling layer is about the same throughout the entire emissivity-controlling layer. In some embodiments, the emissivity-controlling layer preserves the roughness of the substrate surface or the surface below the emissivity-controlling layer. In some embodiments, the emissivity-controlling layer follows the morphology of the surface of the substrate and does not increase or change the roughness of the substrate surface or the surface below the emissivity-controlling layer. In some embodiments, the measured roughness of an emissivity-controlling layer is the roughness of the substrate surface or the roughness of the layer below the emissivity-controlling layer. In some embodiments, after deposition of the emissivity-controlling layer, the surface roughness of the diffuser plate is not substantially changed. In some embodiments, after deposition of the emissivity-controlling layer, the surface roughness of the diffuser plate is increased by less than or less than about 100%, 90%. 80%. 70%, 60%, 50%, 45%, 40%, 35%, 30%, 25%, 20%, 15%, 10%, 5%, or any other percentages.

It will be appreciated that the surface roughness of the showerhead having the emissivity-controlling layer formed thereon can influence the emissivity and/or reflectivity of the showerhead surface, at least in part owing to the degree of photon scattering. In various examples described herein the showerhead surface having an emissivity-controlling layer according to embodiments deposited thereon can have a roughness value, e.g., a root mean squared (RMS) roughness, that is less than about 1500 μm, 1400 μm, 1300 μm, 1200 μm, 1100 μm, 1000 μm, 900 μm, 800 μm, 700 μm, 600 μm, 500 μm, 450 μm, 400 μm, 350 μm, 300 μm, 250 μm, 200 μm, 150 μm, 100 μm, 50 μm, or a value in a range defined by any of these values. In some embodiments, the roughness is the average of profile height deviations from the mean line (Rₐ). In some embodiments, the roughness is the root mean square average of profile height deviations from the mean line.

### Anti-Contamination Coating

Under some circumstances, the emissivity-controlling layer may and the chamber environment may need to be mutually protected from each other due to various factors including, e.g., corrosive chemistry, process contamination and particle generations. The inventors have further discovered that these concerns, among others, can be addressed, for particular emissivity-controlling layers described herein, by introducing a coating for a diffuser plate for ALD processes. In some embodiments, the anti-contamination layer has a high corrosion resistance against the precursors, by-products, or any other chemicals generated or used in the deposition chamber during the cyclic deposition process. In some embodiments, the anti-contamination layer has a high corrosion resistance against the cleaning gas. In some embodiments, the anti-contamination layer has a high corrosion resistance against NF₃, F₂, Ar, ClF₃, or combinations thereof.

In some embodiments, the anti-contamination layer may be transparent or translucent. In some embodiments, the anti-contamination layer may comprise a ceramic base coating. In some embodiments, the anti-contamination layer may comprise Al₂O₃. In some embodiments, the anti-contamination layer may comprise Y₂O₃. In some embodiments, the anti-contamination layer may comprise SiO₂. In some embodiments, the anti-contamination layer may comprise Al₂O₃ and Y₂O₃. In some embodiments, the anti-contamination layer may comprise Al₂O₃ and Y₂O₃ nano-laminate. In some embodiments, the anti-contamination layer may comprise mixed Al₂O₃ and Y₂O₃ composite. In some embodiments, the anti-contamination layer may be amorphous. In some embodiments, the anti-contamination layer may comprise crystalline. In some embodiments, the anti-contamination layer may be about 100 nm to about 10 μm, may be about 100 nm, 200 nm, 500 nm, 700 nm, 900 nm, 1 μm, 2 μm, 3 μm, 5 μm, 7 μm, 9 μm, 10 μm, or any number in a range defined by any of these values.

In some embodiments, depositing an anti-contamination coating on the emissivity-controlling layer of a diffuser plate may change the emissivity value of the diffuser plate. In some embodiments, the emissivity value of a diffuser plate may be increased after depositing an anti-contamination coating. In some embodiments, the emissivity value of a diffuser plate may be increased after depositing an anti-contamination coating. In some embodiments, the emissivity value of a diffuser plate may be increased by about 0 to about 100%, may be about 1%, about 5%, about 10%, about 15%, about 20%, about 25%, about 30%, about 35%, about 40%, about 50%, about 55%, about 60%, about 65%, about 70%, about 75%, about 80%, about 85%, about 90%, about 95%, about 100%, or any number in a range defined by any of these values, after depositing an anti-contamination coating.

In some embodiments, the anti-contamination layer may be formed by vapor deposition process, such as an atomic layer deposition (ALD) method. In some embodiments, the anti-contamination coating is conformal, for example, the thickness of the anti-contamination layer is about the same throughout the entire anti-contamination layer. In some embodiments, the anti-contamination layer follows the morphology of the surface of the substrate or the emissivity-controlling layer, and does not substantially increase or change the roughness of the substrate surface or the emissivity-controlling layer. In some embodiments, after deposition of the anti-contamination layer, the surface roughness of the diffuser plate is increased by less than or less than about 100%, 90%. 80%. 70%, 60%, 50%, 45%, 40%, 35%, 30%, 25%, 20%, 15%, 10%, 5%, or any other percentages. The anti-contamination layer and the emissivity-controlling layer have good compatibility.

### D. EXAMPLES

### Example 1—TiNO Film

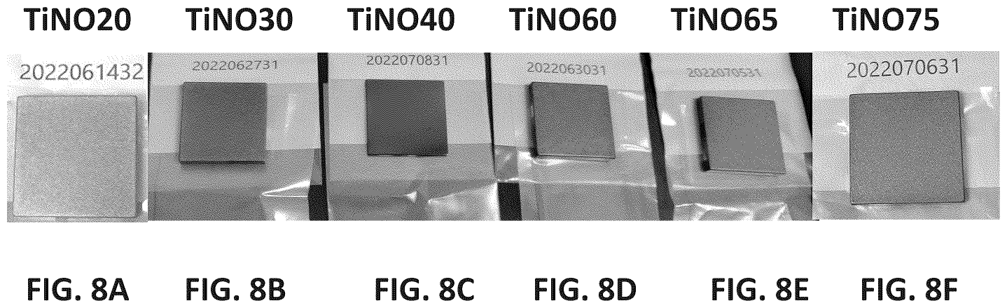

TiNₓO_{y} films with different nitrogen and oxygen ratios were prepared. Table 2 summarizes the atomic percentage (at %) of N, O and Ti, the ratio of N to O, and the emissivity values for different TiNₓO_{y} films according to some embodiments. FIGS. 8A-8F show the photos of the deposited TiNO20, TiNO30, TiNO40, TiNO60, TiNO65 and TiNO75 films respectively. The TiNO films with different N to O ratios were fabricated using a plasma enhanced chemical vapor deposition (PECVD) method or magnetron sputtering. The thicknesses of the TiNₓO_{y} films are about 2 μm. The deposited TiNₓO_{y} films have excellent adhesion.

TABLE 2

| Sample | N | O | Ti | N/O | Total Hemispherical |
|---|---|---|---|---|---|
| Name | (at %) | (at %) | (at %) | ratio | Emittance at 300K |
| TiNO20 | 58 | 7.5 | 34.5 | 7.7 | 0.22 |
| TiNO30 | 44.5 | 22 | 33.5 | 2.0 | 0.28 |
| TiNO40 | 44 | 23 | 33 | 1.9 | 0.41 |
| TiNO55 | 36 | 31.5 | 32.5 | 1.1 | 0.55 |
| TiNO65 | 27 | 40 | 33 | 0.7 | 0.65 |
| TiNO75 | 17.4 | 47.9 | 34.5 | 0.5 | 0.72 |

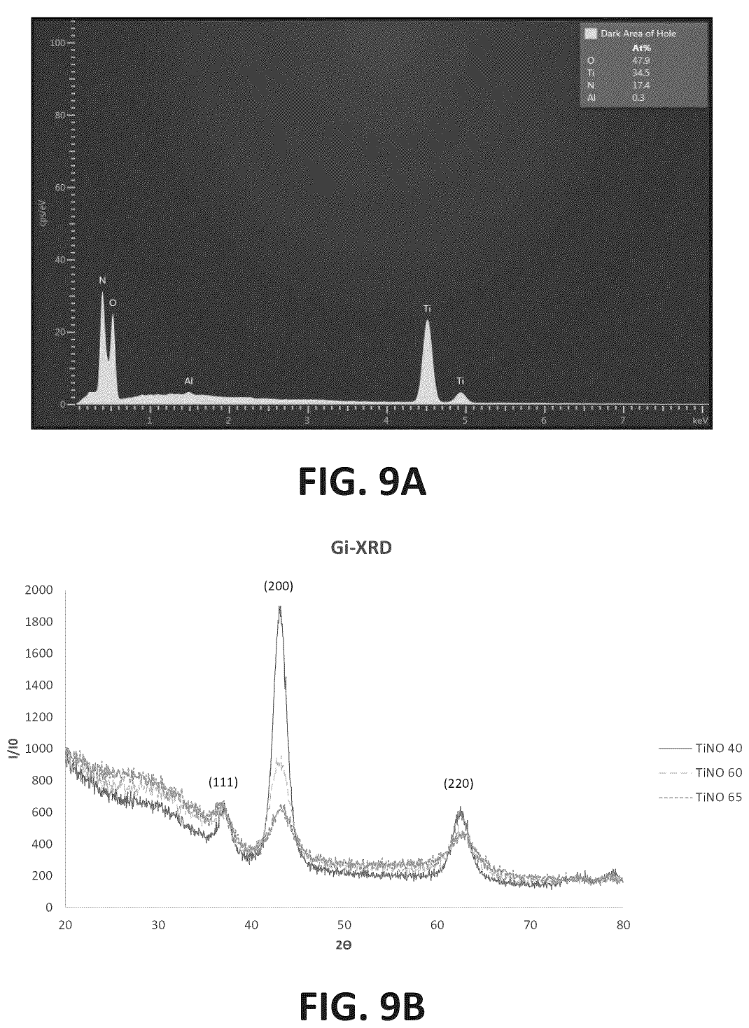

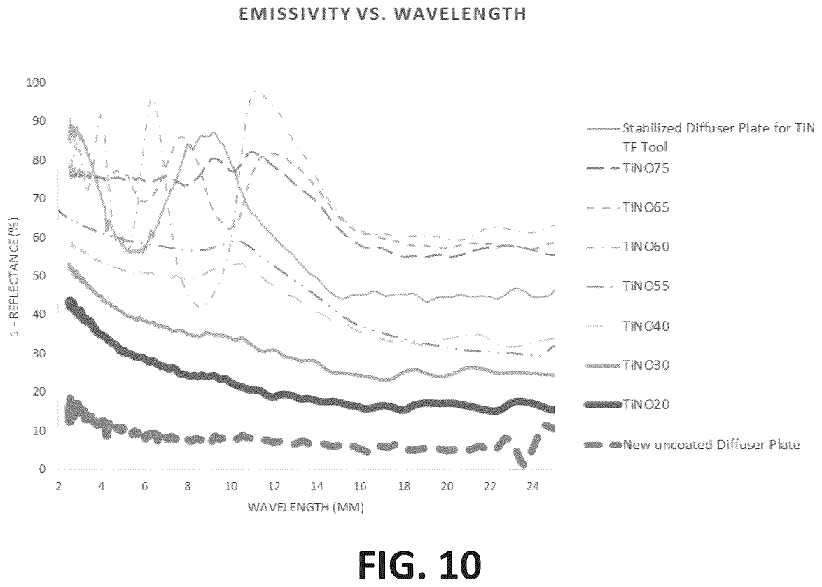

FIG. 9A illustrates the Energy Dispersive X-Ray Spectroscopy (EDS) image of the TiNO75 film. As shown in FIG. 9A, the TiNO75 film comprises 47.5 at % O, 34.5 at % Ti, and 17.4 at % N. FIG. 9B illustrates the X-ray diffraction (XRD) results of the TiNO40, TiNO60 and TiNO65 films. As illustrated in FIG. 9B, the XRD results of the deposited TiNO40, TiNO60 and TiNO65 films all have characteristic peaks for face-centered cubic (FCC) crystal structure. The characteristic peaks of TiNO films shifted towards high angle comparing to TiN XRD spectral. Thus, TiNO40, TiNO60 and TiNO65 films comprise crystalline TiN. In addition, as the TiN characteristic peaks in the XRD result of TiNO40 film have higher intensity comparing to that of TiNO60 film and TiNO65 film, the TiNO 40 film comprises more N than TiNO60 and TiNO65 films. Similarly, the TiNO60 film comprises more N than TiNO65 film.

### Example 2—Emissivity

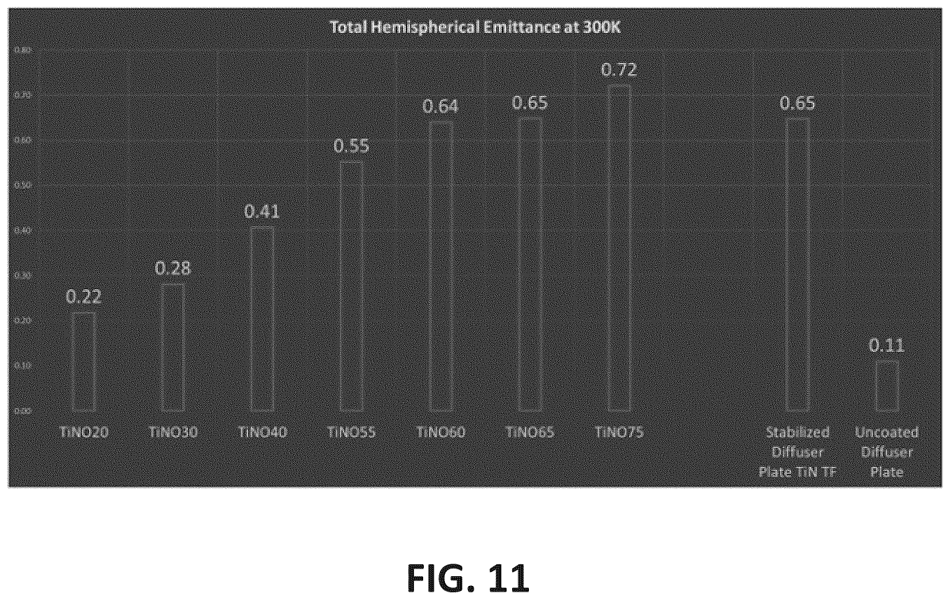

FIG. 11 illustrates the emissivity of an uncoated fresh diffuser plate, an uncoated stabilized diffuser plate, the deposited TiNO20, TiNO30, TiNO40, TiNO55, TiNO60, TiNO65 and TiNO75 films. As shown in FIG. 11, the stabilized diffuser plate has a total hemispherical emittance at 300K of about 0.65 for wavelength between 2 μm to 14 μm. The TiNO20, TiNO30, TiNO40, TiNO55, TiNO60, TiNO65 and TiNO75 films have a total hemispherical emittance at 300K of about 0.22, 0.28, 0.41, 0.55, 0.64, 0.65 and 0.72 respectively for wavelength between 2 μm to 14 μm. A TiNO film with larger number in its sample name indicates that the TiNO film has a relatively large emissivity value. For example, TiNO75 film has a larger emissivity value than TiNO25. As shown in Table 2 and FIG. 11, a TiNO film comprising relatively more 0 and less N has a relatively larger emissivity.

### Example 3—Surface Morphology

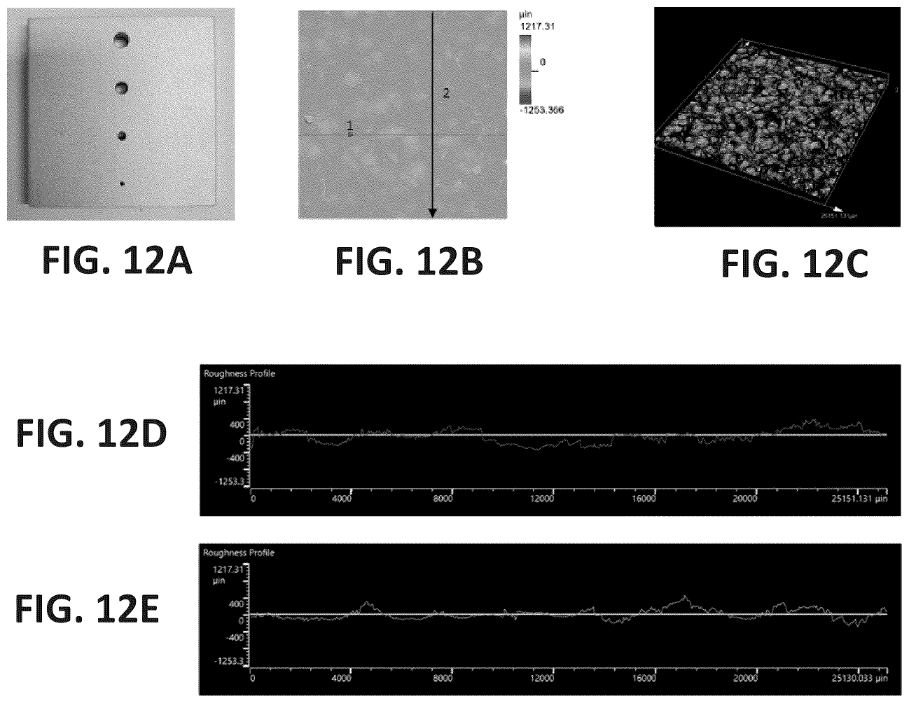

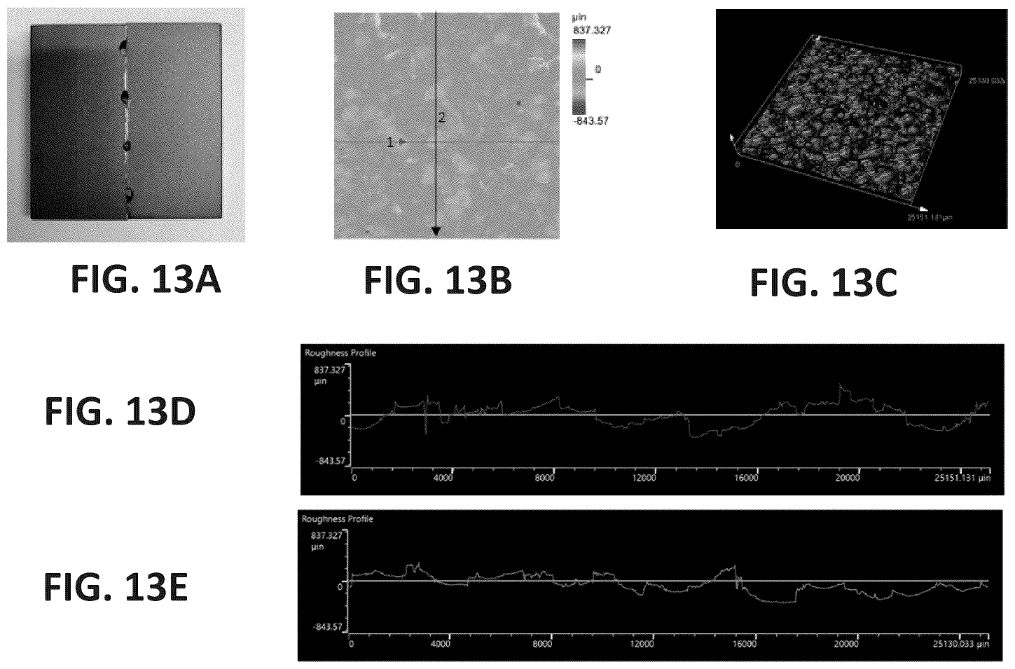

FIG. 12A illustrates an image of the surface of an uncoated substrate sample with coupons made of the same material as a diffuser plate according to some embodiments. In the illustrated embodiment, the sample substrate is made of aluminum. FIG. 12B illustrates a colored height map with 50× magnification of the uncoated sample substrate in FIG. 12A. The surface profiles along a horizontal line 1 and a vertical line 2 as shown in FIG. 12B were analyzed. FIG. 12C illustrates a three-dimensional (3D) map of the surface topography with 50× magnification of the uncoated sample substrate in FIG. 12A. FIG. 12D illustrates the surface profile along the horizontal line 1 shown in FIG. 12B and FIG. 12E illustrates the surface profile along the vertical line 2 shown in FIG. 12B. Table 3A summarizes the roughness along the horizontal line 1 and vertical line 2 in FIG. 13A calculated in different ways. As used herein, Rₐ is the average roughness and R_{q} is the root mean square roughness.

TABLE 3A

| Sample | Rp | Rv | Rz | Rc | Rt | Ra | Rq | | | Rsm |
|---|---|---|---|---|---|---|---|---|---|---|
| No | (μin) | (μin) | (μin) | (μin) | (μin) | (μin) | (μin) | Rsk | Rku | (μin) |
| 1 | 348.7 | 326.7 | 675.5 | 320 | 675.5 | 127.3 | 152.7 | −0.12 | 2.1 | 2951 |
| 2 | 424.4 | 344.9 | 769.4 | 176.8 | 769.4 | 89.3 | 116.1 | 0.43 | 3.8 | 1295 |

FIG. 13A illustrates a photograph of a sample substrate with coupon coated with a TiNO75 layer according to some embodiments. FIG. 13B illustrates a colored height map with 50× magnification of the sample substrate coated with a TiNO75 layer in FIG. 13A. The surface profiles along a horizontal line 1 and a vertical line 2 as shown in FIG. 13B were analyzed. FIG. 13C illustrates a three-dimensional (3D) map of the surface topography with 50× magnification of the sample substrate coated with the TiNO75 layer as shown in FIG. 13A. FIG. 13D illustrates the surface profile along a horizontal line 1 shown in FIG. 13B and FIG. 13E illustrates the surface profile along a vertical line 2 shown in FIG. 13B. Table 3B summarizes the roughness along the horizontal line 1 and vertical line 2 in FIG. 13B calculated in different ways. As used herein, Rₐ is the average roughness and R_{q} is the root mean square roughness.

TABLE 3B

| Sample | Rp | Rv | Rz | Rc | Rt | Ra | Rq | | | Rsm |
|---|---|---|---|---|---|---|---|---|---|---|
| No. | (μin) | (μin) | (μin) | (μin) | (μin) | (μin) | (μin) | Rsk | Rku | (μin) |
| 1 | 496.2 | 364 | 860.2 | 478.8 | 860.2 | 144.3 | 170.1 | −0.10 | 2.2 | 3848 |
| 2 | 341.3 | 236.4 | 577.6 | 238.9 | 577.6 | 84.5 | 108 | −0.06 | 3.0 | 2036 |

As illustrated in Tables 3A and 3B, the average roughness Rₐ of a horizontal line on the sample substrate before coating is about 127.3 μin, and the average roughness Rₐ of a horizontal line on the sample substrate after coating is about 144.3 μin. The root mean square roughness R_{q} of a horizontal line on the sample substrate before coating is about 152.7 μin, and the root mean square roughness R_{q} of a horizontal line on the sample substrate after coating is about 170.1 μin. The average roughness Ra of a vertical line on the sample substrate before coating is about 89.3 μin, and the average roughness Ra of a vertical line on the sample substrate after coating is about 116.1 μin. The root mean square roughness R_{q} along the vertical line as shown in FIG. 12B on the sample substrate before coating is about 152.7 μin, and the root mean square roughness R_{q} along the vertical line as shown in FIG. 13B on the sample substrate after coating is about 108.0 μin. These results show that the roughness of the sample substrate has not been substantially changed by the formation of the TiNO layer throughout the whole substrate sample and the deposited TiNO layer is uniform and conformal.

### Example 4—Double-Layer Coating

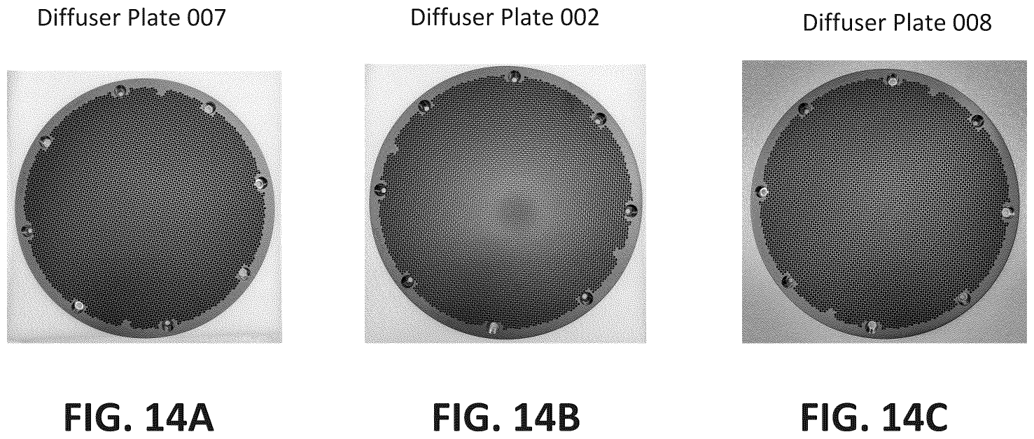

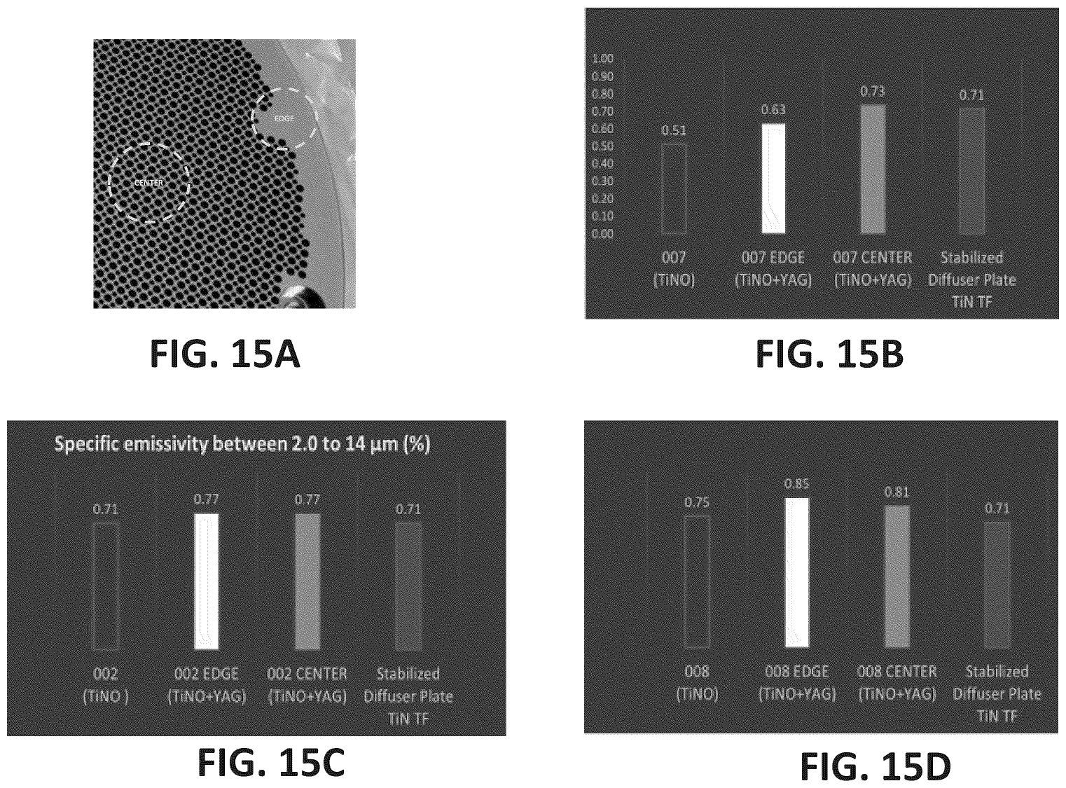

Diffuser plates coated with different double-layer coatings were prepared. FIGS. 14A-14C illustrate diffuser plates 007, 002, and 008 respectively, which are coated with different double-layer coatings according to some embodiments. The diffuser plate was first coated with a TiNₓO_{y} emissivity-controlling layer and then a YAG anti-contamination layer. The TiNₓO_{y} layer is about 2 μm. The YAG layer is about 500 nm or 1000 nm. Table 4 summarizes the emissivity values of fresh diffuser plates, emissivity-controlling layers, and diffuser plates 007, 002, and 008 coated with double-layer coatings. FIG. 15A illustrates the edge and center area on a diffuser plate.

TABLE 4

| | Emissivity Values | | | |
|---|---|---|---|---|
| Sample | Fresh Diffuser | | TiNₓO_{y} + YAG | TiNₓO_{y} + YAG |
| Name | Plate | TiNₓO_{y} | (Edge) | (Center) |
| 007 | 0.09 | 0.51 | 0.63 | 0.73 |
| 002 | 0.09 | 0.71 | 0.77 | 0.77 |
| 008 | 0.09 | 0.75 | 0.85 | 0.81 |

As shown in Table 4, the emissivity values of the diffuser plates 007, 002, and 008 with different TiNₓO_{y} films increase to 0.51, 0.71 and 0.75 respectively. The x to y ratio of the TiNₓO_{y} film for diffuser plates 007 is larger than that of diffuser plate 002 and 008, and the x to y ratio of the TiNₓO_{y} film for diffuser plates 002 is larger than that of diffuser plate 008.

As shown in Table 4, the emissivity values of the diffuser plates 007, 002 and 008 may be increased after being coated with a YAG anti-contamination layer. In addition, the emissivity values at the edge are smaller than the emissivity values at the center area. Without being bound to any theory, this difference may be due to that there are less holes with high emissivity values at the edge area.

FIGS. 15B-15D summarize the emissivity values of diffuser plates 007, 002 and 008 with different TiNₓO_{y} layers, with different double-layer coatings, and a stabilized diffuser plate without any coating.

### E. EXAMPLE EMBODIMENTS

The following example embodiments identify some possible permutations of combinations of features disclosed herein, although other permutations of combinations of features are also possible.

1. A gas diffuser plate in a cyclic deposition chamber, the gas diffuser plate as fabricated comprising:
a substrate diffuser plate having a substrate emissivity; and
a coating formed on the substrate diffuser plate, wherein the gas diffuser plate having the substrate diffuser plate coated with the coating has an emissivity higher than the substrate emissivity.

2. The gas diffuser plate of Embodiment 1, wherein the coating comprises:
a first layer formed on the substrate diffuser plate and comprising a first material configured to modulate the emissivity of the gas diffuser plate; and
a second layer comprising a second corrosion-resistant material.

3. The gas diffuser plate of Embodiment 2, wherein the first layer is configured to modulate the emissivity of the gas diffuser plate to a value between about 0.2 and about 0.9.

4. The gas diffuser plate of Embodiment 2 or 3, wherein a side of the gas diffuser plate coated with the coating is configured to face a wafer when present in the cyclic deposition chamber, wherein the first layer is configured to modulate the emissivity of the gas diffuser plate to match an emissivity of a deposited material on the wafer.

5. The gas diffuser plate of any one of Embodiments 2-4, wherein the first material comprises a mixture of titanium oxide (TiOₓ) and titanium nitride (TiNₓ).

6. The gas diffuser plate of any one of Embodiments 2-5, wherein the first material comprises titanium nitride oxide (TiNₓO_{y}).

7. The gas diffuser plate of Embodiment 6, wherein the emissivity is at least partially based on the ratio of nitrogen and oxygen in TiNₓOy.

8. The gas diffuser plate of any one of Embodiments 2-7, wherein the second layer is configured to reduce particle contamination generated from the corrosion of the substrate diffuser plate or the first layer in a cleaning process.

9. The gas diffuser plate of any one of Embodiments 2-8, wherein the second layer is resistant to the corrosion of a cleaning gas when present in the cyclic deposition chamber.

10. The gas diffuser plate of Embodiment 9, wherein the cleaning gas comprises NF₃, F₂, Ar, ClF₃, or combinations thereof.

11. The gas diffuser plate of any one of Embodiments 2-10, wherein the second material comprises yttrium aluminum garnet (YAG).

12. The gas diffuser plate of any one of Embodiments 2-11, wherein the second material comprises Al₂O₃, Y₂O₃, or a combination thereof.

13. The gas diffuser plate of any one of Embodiments 2-12, wherein the second material is transparent or translucent.

14. The gas diffuser plate of any one of Embodiments 2-13, wherein the first layer of the first material is deposited by a method comprising plasma enhanced chemical vapor deposition (PECVD) process or magnetron sputtering.

15. The gas diffuser plate of any one of Embodiments 2-14, wherein the second material is deposited by a method comprising atomic layer deposition (ALD).

16. The gas diffuser plate of any one of Embodiments 2-15, wherein the first layer of the first material reduces the amount of radiation emission from the wafer being reflected by the gas diffuser plate.

17. The gas diffuser plate of any one of Embodiments 2-16, wherein the second layer is placed on top of the first layer.

18. A gas diffuser plate for delivering precursor gases in a cyclic deposition chamber configured to deposit a material on a wafer, the gas diffuser plate as fabricated comprising:
a substrate diffuser plate having a substrate emissivity; and
a coating formed on the substrate diffuser plate at a side configured to face the wafer when present in the cyclic deposition chamber,
wherein the gas diffuser plate having the substrate diffuser plate coated with the coating has an emissivity, and
wherein a difference between the value of the emissivity of the gas diffuser plate and the value of an emissivity of the material when deposited on the wafer is smaller than the difference between the value of the substrate emissivity and the value of the emissivity of the deposited material.

19. The gas diffuser plate of Embodiment 18, wherein the coating comprises:
a first layer formed on the substrate diffuser plate and comprising a first material configured to modulate the emissivity of the gas diffuser plate; and
a second layer comprising a second material configured to reduce particle generation from the corrosion of the first layer or the substrate diffuser plate.

20. The gas diffuser plate of Embodiment 19, wherein the emissivity of the first layer is about 0.2 to about 0.9.

21. The gas diffuser plate of Embodiment 19 or 20, wherein the first material comprises a mixture of titanium oxide (TiOₓ) and titanium nitride (TiNₓ).

22. The gas diffuser plate of any one of Embodiments 19-21, wherein the first material comprises titanium nitride oxide (TiNₓO_{y}).

23. The gas diffuser plate of Embodiment 22, wherein the emissivity of the first material is at least partially based on the ratio of nitrogen and oxygen in TiNₓOy.

24. The gas diffuser plate of any one of Embodiments 19-23, wherein the second layer is corrosion resistant to a cleaning gas.

25. The gas diffuser plate of Embodiment 24, wherein the cleaning gas comprises NF₃, F₂, Ar, ClF₃, or combinations thereof.

26. The gas diffuser plate of any one of Embodiments 19-25, wherein the second material comprises yttrium aluminum garnet (YAG).

27. The gas diffuser plate of any one of Embodiments 19-26, wherein the second material comprises Al₂O₃, Y₂O₃, or a combination thereof.

28. The gas diffuser plate of any one of Embodiments 19-27, wherein the first layer of the first material is deposited by a method comprising plasma enhanced chemical vapor deposition (PECVD) process or magnetron sputtering.

29. The gas diffuser plate of any one of Embodiments 19-28, wherein the first layer reduces the amount of radiation emission from a wafer being reflected by the gas diffuser plate.

30. The gas diffuser plate of any one of Embodiments 19-29, wherein the second layer is placed on top of the first layer.

31. A method of fabricating a diffuser plate for delivering precursor gases in a cyclic deposition chamber, the method comprising:
providing a substrate diffuser plate having a substrate emissivity; and
coating the substrate diffuser plate with a coating such that the gas diffuser plate having the substrate diffuser plate coated with the coating as fabricated has an emissivity higher than the substrate emissivity.

32. The method of Embodiment 31, wherein the coating comprises:
forming a first layer of a first material having a selected emissivity such that the diffuser plate has the emissivity; and
forming a second layer of a second material on top of the first material.

33. The method of Embodiment 31 or 32, wherein the emissivity is between about 0.2 to about 0.7.

34. The method of any one of Embodiments 31-33, wherein forming the first layer of the first material comprising plasma enhanced chemical vapor deposition (PECVD) or magnetron sputtering.

35. The method of any one of Embodiments 31-34, wherein forming the second layer of the second material comprising ALD.

36. The method of any one of Embodiments 31-35, wherein the selected emissivity is at least partially related to an emissivity of the material to be deposited.

37. The method of any one of Embodiments 31-36, wherein the first material comprises titanium nitride oxide (TiNₓO_{y}).

38. The method of any one of Embodiments 31-37, wherein the selected emissivity of the first material is at least partially determined by the ratio of nitrogen and oxygen in TiNₓOy.

39. The method of any one of Embodiments 31-28, wherein the selected emissivity is at least partially related to an emissivity of the material to be deposited.

40. The method of any one of Embodiments 31-39, wherein the second material comprises yttrium aluminum garnet (YAG).

41. The method of any one of Embodiments 31-40, wherein the second material comprises Al₂O₃, Y₂O₃, or a combination thereof.

42. The method of any one of Embodiments 31-41, wherein the second material is resistant to a cleaning gas.

43. The method of Embodiment 42, wherein the cleaning gas comprises NF₃, F₂, Ar, ClF₃, or combinations thereof.

44. The method of Embodiment 42 or 43, wherein the second material is configured to reduce particle contamination.

45. An emissivity-controlling layer for a diffuser plate for a cyclic deposition process, the emissivity-controlling layer configured to modulate an emissivity of a diffuser plate to an emissivity of a material to be deposited by the cyclic deposition process.

46. The emissivity-controlling layer of Embodiment 45, wherein the emissivity-controlling layer comprises titanium nitride oxide (TiNₓO_{y}).

47. The emissivity-controlling layer of Embodiment 45 or 46, wherein the emissivity of the emissivity-controlling layer is at least partially determined by the ratio of nitrogen and oxygen in TiNₓOy.

Although the present invention has been described herein with reference to the specific embodiments, these embodiments do not serve to limit the invention and are set forth for illustrative purposes. It will be apparent to those skilled in the art that modifications and improvements can be made without departing from the spirit and scope of the invention.

Such simple modifications and improvements of the various embodiments disclosed herein are within the scope of the disclosed technology, and the specific scope of the disclosed technology will be additionally defined by the appended claims.

In the foregoing, it will be appreciated that any feature of any one of the embodiments can be combined or substituted with any other feature of any other one of the embodiments.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while features are presented in a given arrangement, alternative embodiments may perform similar functionalities with different components and/or sensor topologies, and some features may be deleted, moved, added, subdivided, combined, and/or modified. Each of these features may be implemented in a variety of different ways. Any suitable combination of the elements and acts of the various embodiments described above can be combined to provide further embodiments. The various features and processes described above may be implemented independently of one another, or may be combined in various ways. All possible combinations and subcombinations of features of this disclosure are intended to fall within the scope of this disclosure.

What is claimed is:

1. A gas diffuser plate in a cyclic deposition chamber, the gas diffuser plate as fabricated comprising:
a substrate diffuser plate having a substrate emissivity; and
a coating formed on the substrate diffuser plate, wherein the gas diffuser plate having the substrate diffuser plate coated with the coating has an emissivity higher than the substrate emissivity.

2. The gas diffuser plate of claim 1, wherein the coating comprises:
a first layer formed on the substrate diffuser plate and comprising a first material configured to modulate the emissivity of the gas diffuser plate; and
a second layer comprising a second corrosion-resistant material.

3. The gas diffuser plate of claim 2, wherein the first layer is configured to modulate the emissivity of the gas diffuser plate to a value between about 0.2 and about 0.9.

4. The gas diffuser plate of claim 2, wherein a side of the gas diffuser plate coated with the coating is configured to face a wafer when present in the cyclic deposition chamber, wherein the first layer is configured to modulate the emissivity of the gas diffuser plate to match an emissivity of a deposited material on the wafer.

5. The gas diffuser plate of claim 2, wherein the first material comprises titanium nitride oxide (TiNₓO_{y}) or a mixture of titanium oxide (TiOₓ) and titanium nitride (TiNₓ).

6. The gas diffuser plate of claim 5, wherein the emissivity is at least partially based on the ratio of nitrogen and oxygen in TiNₓO_{y} or the mixture of TiOₓ and TiNₓ.

7. The gas diffuser plate of claim 2, wherein the second layer is configured to reduce particle contamination generated from the corrosion of the substrate diffuser plate or the first layer in a cleaning process.

8. The gas diffuser plate of claim 2, wherein the second layer is resistant to the corrosion of a cleaning gas when present in the cyclic deposition chamber.

9. The gas diffuser plate of claim 8, wherein the cleaning gas comprises NF₃, F₂, Ar, ClF₃, or combinations thereof.

10. The gas diffuser plate of claim 2, wherein the second material comprises yttrium aluminum garnet (YAG), Al₂O₃, Y₂O₃, or combinations thereof.

11. The gas diffuser plate of claim 2, wherein the second material is transparent or translucent.

12. The gas diffuser plate of claim 2, wherein the first layer of the first material is deposited by a method comprising plasma enhanced chemical vapor deposition (PECVD) process or magnetron sputtering.

13. The gas diffuser plate of claim 2, wherein the second material is deposited by a method comprising atomic layer deposition (ALD).

14. The gas diffuser plate of claim 2, wherein the first layer of the first material reduces the amount of radiation emission from the wafer being reflected by the gas diffuser plate.

15. The gas diffuser plate of claim 2, wherein the second layer is placed on top of the first layer.

16. A gas diffuser plate for delivering precursor gases in a cyclic deposition chamber configured to deposit a material on a wafer, the gas diffuser plate as fabricated comprising:
a substrate diffuser plate having a substrate emissivity; and
a coating formed on the substrate diffuser plate at a side configured to face the wafer when present in the cyclic deposition chamber,
wherein the gas diffuser plate having the substrate diffuser plate coated with the coating has an emissivity, and
wherein a difference between the value of the emissivity of the gas diffuser plate and the value of an emissivity of the material when deposited on the wafer is smaller than the difference between the value of the substrate emissivity and the value of the emissivity of the deposited material.

17. The gas diffuser plate of claim 16, wherein the coating comprises:
a first layer formed on the substrate diffuser plate and comprising a first material configured to modulate the emissivity of the gas diffuser plate; and
a second layer comprising a second material configured to reduce particle generation from the corrosion of the first layer or the substrate diffuser plate.

18. The gas diffuser plate of claim 16, wherein the emissivity of the first layer is about 0.2 to about 0.9.

19. The gas diffuser plate of claim 16, wherein the first material comprises titanium nitride oxide (TiNₓO_{y}) or a mixture of titanium oxide (TiOₓ) and titanium nitride (TiNₓ).

20. The gas diffuser plate of claim 19, wherein the emissivity of the first material is at least partially based on the ratio of nitrogen and oxygen in TiNₓO_{y} or the mixture of TiOₓ and TiNₓ.

21. The gas diffuser plate of claim 16, wherein the second layer is corrosion resistant to a cleaning gas.

22. The gas diffuser plate of claim 21, wherein the cleaning gas comprises NF₃, F₂, Ar, ClF₃, or combinations thereof.

23. The gas diffuser plate of claim 16, wherein the second material comprises yttrium aluminum garnet (YAG), Al₂O₃, Y₂O₃, or combinations thereof.

24. The gas diffuser plate of claim 16, wherein the first layer of the first material is deposited by a method comprising plasma enhanced chemical vapor deposition (PECVD) process or magnetron sputtering.

25. The gas diffuser plate of claim 16, wherein the first layer reduces the amount of radiation emission from a wafer being reflected by the gas diffuser plate.

26. The gas diffuser plate of claim 16, wherein the second layer is placed on top of the first layer.
